(19) United States
(12) Patent Application Publication
(10) Pub. No.: US 2007/0223613 A1
(43) Pub. Date: Sep. 27, 2007

(54) Viberbi Decoding Quality Indicator Based on Sequenced Amplitude Margin (Sam)

(75) Inventors: Coen Adrianus Verschuren, Eindhoven (NL); Alexander V. Padiy, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/568,725

(22) PCT Filed: May 9, 2005
(86) PCT No.: PCT/IB05/51511

§ 371 Date: Nov. 6, 2006

(30) Foreign Application Priority Data
May 13, 2004 (EP) 04102081.9

(51) Int. Cl. H03M 13/00

(52) U.S. Cl. 375/265; 702/189; 714/704

(57) ABSTRACT

A system for generating a quality indicator for a trellis decoded signal based on the path metrics of the decoding is presented. An apparatus comprises a path metric processor (105) which determines path metric differences between two path metrics entering a state of a trellis decoder 103. A measured distribution processor (107) orders the path difference metrics to generate a measured distribution. An analysis distribution processor (109) fits a distribution being the sum of a first and second distribution path to the measured distribution. A quality indicator processor (111) determines a quality indicator in response to the fitted distribution. In particular, the first distribution may be associated with correct sign path metric differences and the second distribution may be associated with incorrect sign path metric differences. The quality indicator processor (111) preferably determines the quality indicator in response to only the first distribution thereby reducing the degradation caused by the incorrect sign path metric differences.

### FIELD OF THE INVENTION

The invention relates to a method and apparatus for generating a quality indicator for a decoded signal and in particular, but not exclusively, to a quality indicator for a reading device for reading from a storage medium, such as an optical disk.

### BACKGROUND OF THE INVENTION

In recent years, the use of digital distribution and communication of for example audio visual content has increased substantially. Also, storage of digital data on removable or fixed storage means has become of increasing importance. For example, the increased popularity of personal computers and digital consumer devices has resulted in a huge market for storage devices such as hard disks or CD (Compact Disc) and DVD (Digital Versatile Disc) recorders and players. As another example, digital transmission has replaced, or currently is replacing, analog transmissions in many applications such as for example for broadcast of TV signals.

Digital signals are typically encoded using forward error correcting coding to reduce the number of errors generated e.g. by noise in a communication channel or reading errors when reading from a storage medium. For example, block codes, such as Hamming codes, or convolutional codes, such as Viterbi codes, are frequently used to encode digital signals to provide an improved error performance.

In many applications, it is important to determine an indication of the quality of the decoded signal. For example, in the field of optical disk systems a performance or quality indicator that indicates the reliability of the generated decoded bit stream is important. In particular, the quality indicator may be used to control the optical disk system. For example, as the quality indicator indicates a degraded quality, the optical disk system may reduce the reading speed to provide an improved reliability.

In order to achieve higher densities in optical disk systems, Partial Response Maximum Likelihood (PRML) detection methods are preferred. A PRML detection algorithm does not simply detect an individual bit in response to a threshold detection for the specific disk domain, but generates a soft decision and performs data detection based on a plurality of soft decisions, thereby taking into account the interrelationship between the generated values for different bits. In particular, a Viterbi trellis based decoder is frequently used wherein path metrics are generated in accordance with a suitable path metric criterion and the bit values are determined as the bit values of the path resulting in the lowest error path metric. The path metrics may take into account constraints and restrictions intentionally imposed during writing of the optical disk but may additionally or alternatively take into account inter symbol interference introduced by unintentional physical properties of the system. For example, communication though a bandwidth limited channel may introduce inter symbol interference or the physical dimension of bit domains may result in an area overlap thereby introducing a dependency between data values read from a disk.

At higher densities, conventional threshold detection of data from an optical disc does not result in satisfactory performance. Accordingly, quality indicators determined from related performance measurements, such as jitter, are no longer suitable. Furthermore, evaluating and optimizing the disk system performance based directly on bit error rate (BER) measurements have some important disadvantages. Firstly, it is required that many data bits are evaluated to provide an accurate BER estimate (in particular for low error rates). Secondly, a known data pattern is required to be compared to the received data bits. Thirdly, the BER measurements are sensitive to media defects such as small scratches or dust. Therefore, new methods are needed.

Recently, a new procedure for determining a quality indicator, which for example may be suitable for high density optical disk systems, has been proposed. The method is known as the Sequenced Amplitude Margin (SAM) procedure and is further described in United States of America patent U.S. 2003/0043939 A1.

In the SAM procedure, a distribution of the path metrics of a trellis based Viterbi decoder is generated and used to generate a quality indicator. In particular, a SAM value is defined as the difference between two path metrics of two paths leading to a correct state in the trellis and in particular as the difference between the path metric of the correct path and the path metric of the incorrect paths having the lowest path metric (assuming that the path metrics decrease for increased probability that the path is correct i.e. that the path metric is a distance measure). The SAM values are determined for each bit and a distribution in the form of a histogram is generated. When an error occurs the path metric of the correct path is higher than that of the other path and accordingly a negative SAM value is calculated. Hence, if the data is known during the detection, and thus also the correct states, each negative SAM value indicates the occurrence of a detection error since the Viterbi decoder will chose the path having the lowest path metric, which in this case will correspond to the incorrect path.

Accordingly, an error rate may be determined by evaluating the fraction of the distribution which has a SAM value below zero. In particular, the SAM procedure comprises fitting a normalized Gaussian (normal) distribution to the SAM values and determining the area of the distribution corresponding to negative SAM values. Hence, the error rate is estimated by extrapolating a histogram of SAM values over the negative x-axis with the error rate corresponding to the total area below the curve for negative SAM values.

However, a problem associated with this approach is that in most applications the data to be detected is not known during decoding. Accordingly, the SAM values are calculated as the difference between the minimum path and the second smallest path during the path search process of the Viterbi decoder. As this decision process will always select the lowest path metric, the calculated SAM values will always be positive. In other words, the SAM values will not accurately reflect the path metric difference when decoding errors occur.

Since the SAM values computed in this way are always non-negative, the histogram of SAM values will be distorted. The SAM procedure may still be applied to determine a quality indicator by fitting a Gaussian distribution and using this to extrapolate the histogram for negative SAM values thereby allowing an error rate to be determined. This approach assumes that the SAM histogram within the range of fitting can be approximated as a normal distribution and that this distribution is representative of the correct SAM values below zero.

However, due to the distortion introduced by the SAM values always being measured as positive values, the Gaussian distribution fitted to the SAM histogram is generally not an accurate representation. In particular when the error rate is high, such as at higher densities, asymmetry or e.g. high tilt angles, the assumption of a Gaussian distribution is not accurate. In particular, this may result in accurate or wrong parameters for the Gaussian distribution being determined and in particular a mean and standard deviation may be determined which does not result in a Gaussian distribution accurately reflecting negative SAM values. Thus, an inaccurate quality indicator is determined. Furthermore, as the error and inaccuracies typically increase for increasing error rates, the accuracy worsens in the more critical conditions which determine the system margins.

Hence, an improved system for generating a performance indicator for a decoded signal would be advantageous and in particular a system allowing for increased accuracy of the quality indicator would be advantageous.

### SUMMARY OF THE INVENTION

Accordingly, the Invention preferably seeks to mitigate, alleviate or eliminate one or more of the above mentioned disadvantages singly or in any combination.

According to a first aspect of the invention, there is provided an apparatus for generating a quality indicator for a decoded signal, the apparatus comprising: means for determining a plurality of path metric differences, each path metric difference being a difference between at least two path metrics entering a state of a trellis based decoder; means for generating a measured distribution by ordering the plurality of path metric differences; means for determining parameters of an analysis distribution by fitting the analysis distribution to the measured distribution in a predetermined range of path metric differences; means for determining a quality indicator for the decoded signal in response to the analysis distribution; and wherein the analysis distribution is the sum of a first and second distribution in the predetermined range.

The invention may provide for an improved way of generating a quality indicator for a decoded signal and may in particular generate a performance indicator with improved accuracy. The analysis distribution may provide an improved fit and in particular the first distribution may correspond to one characteristic or cause and the second distribution may correspond to a different characteristic or cause. For example, the first characteristic may correspond to a characteristic of the measured distribution suitable for determining a quality indicator and the second characteristic may correspond to a distortion characteristic of the measured distribution. This may allow a desired and undesired characteristic to be separated.

As a specific example, for a SAM procedure, the first distribution may be associated with path metric differences for correct paths and the second distribution may be associated with path metric differences of error paths resulting in sign inversions of the path metric difference. Hence, an improved fit to the measurement distribution comprising both elements may be achieved and a differentiation between the desired and the sign inverted path metric differences may be achieved.

The trellis based decoder may in particular be a Viterbi decoder for decoding Viterbi encoded signals and/or partial response data and/or data comprising inter symbol interference. The term Viterbi decoder is considered to include the term Viterbi equalizer. The measured distribution may in particular be a normalized histogram of path metric differences corresponding to a probability density function. The first, second and analysis distribution are preferably probability density functions.

According to a preferred feature of the invention, the means of determining the quality indicator is operable to determine the quality indicator in response to only the first distribution.

This may provide an improved quality indicator and in particular a quality indicator with improved accuracy. A more accurate fit of the analysis distribution to the measured distribution may be achieved. Furthermore, the second distribution may reflect an error or distortion effect resulting in a first distribution which more accurately reflects the desired characteristics or parameter. For example, for a SAM procedure the first distribution may be associated with path metric differences for correct paths and the second distribution may be associated with path metric differences of error paths. By only using the first distribution corresponding to the correct paths for determining the quality indication, the effect of the path metrics of the incorrect paths may be removed or reduced. Hence, the impact of the sign inversion for path metric differences of incorrect paths may be removed or reduced thereby resulting in a significantly improved quality indication.

According to a preferred feature of the invention, the means of determining a quality indicator is operable to determine the quality indicator in response to the first distribution in a range of path difference metrics below zero. In many applications, this may provide an appropriate and accurate quality indication as negative path metric differences indicates errors. Hence, the invention may allow a simple determination of a quality indicator by extrapolating a measured distribution comprising only positive path metric differences to negative path metric difference values and evaluating these. For example, for a SAM procedure, the first distribution may correspond to the positive path metric differences for correct paths. On the basis of these samples, a first distribution may be determined from which the negative path metric difference values corresponding to errors may be estimated. By evaluating these negative path metric differences an accurate signal indicator may be determined. In particular, a first distribution being a probability density function may be integrated from −∞ to zero to provide an error rate.

According to a preferred feature of the invention, the means for determining the plurality of path metric differences is operable to determine a path metric difference for a state of the trellis based decoder as the absolute path metric difference between the best metric path and the second best metric path leading to the state, the state being designated a correct state by the trellis based decoder.

For example, if a path metric is used wherein an increasing value indicates an increasing probability of the path being a correct path, the means for determining the plurality of path metric differences is operable to determine a path metric difference by subtracting the second highest path metric from the highest path metric. As another example, if a path metric is used wherein a decreasing value indicates an increasing probability of the path being a correct path, the means for determining the plurality of path metric differences is operable to determine a path metric difference by subtracting the second lowest path metric from the lowest path metric. Hence, the path metric difference is determined as the difference between the two most likely paths entering a state. This provides a suitable way of determining a path metric difference in situations where the correct data is not known such as in a non-data aided and/or non-decision aided decoding process. Hence, the invention may provide an improved quality indicator without requiring known data.

The state may be designated as the correct state in accordance with any suitable criterion. In particular, the state is designated a correct state when it is part of the feedback path selected by the Viterbi decoder when generating the decoded signal. Hence, the designated state is part of the path having the best accumulated path metric and is thus assumed to be the correct state.

According to a preferred feature of the invention, the predetermined range corresponds to path metric differences from zero to an average path metric difference of the measured distribution. This provides a suitable predetermined range for many applications such as for many high density optical disc readers.

According to a preferred feature of the invention, the predetermined range corresponds to path metric differences from zero to an upper path metric difference corresponding to a value of the measured distribution of a fraction of between 0.2 and 0.6 of the maximum value of the measured distribution. This provides a particularly advantageous range for many applications such as for many high density optical disc readers and in particular provides an advantageous trade off between restricting a predetermined range to the vicinity of the negative path metric difference values and obtaining sufficient number of samples.

According to a preferred feature of the invention, the predetermined range corresponds to path metric differences from zero to an upper path metric difference corresponding to a value of the measured distribution of a fraction of around 0.4 of the maximum value of the measured distribution. For many applications, such as for many high density optical disc readers, this provides the optimal trade off between restricting a predetermined range to the vicinity of the negative path metric difference values and obtaining sufficient number of samples.

According to a preferred feature of the invention, the second distribution is substantially equal to the first distribution mirrored around a path metric difference of substantially zero.

Specifically, p₁(x) may be substantially equal to p₂(-x), where p₁(x) is the first distribution and p₂(x) is the second distribution. This may be particularly advantageous in applications where a distortion effect is introduced by only an absolute value of the path metric differences being determined as the analysis distribution may take into account the distortion of the measured distribution introduced thereby. Hence, the mirroring of negative path metric differences into positive path metric differences may be estimated by the second density function allowing the first distribution to provide a more accurate fit to the non-mirrored data of the measured distribution. This may provide an improved quality indicator. This may be particularly advantageous in for example a SAM procedure not relying on known data.

According to a preferred feature of the invention, the first and second distributions are Gaussian distributions. Preferably the first and second distributions are Gaussian (or Normal) distributions having substantially equal standard deviations and average values of substantially equal absolute value but with opposite signs. These distributions provide particularly suitable distributions for determining an accurate quality indicator and are in many applications particularly suitable for achieving an analysis distribution closely fitting the measured distribution.

According to a preferred feature of the invention, the quality indicator is a bit error rate. The invention may thus provide an easy to implement way of generating an accurate bit error rate indicator.

According to a second aspect of the invention, there is provided a reading device for reading from a storage medium; the reading device comprising: a reader for reading an encoded data signal from the storage medium; a trellis based decoder for generating a decoded data signal from the encoded data signal; and an apparatus for generating a quality indicator for the decoded data signal as described above.

The invention may provide for an improved reading device and in particular for a data reading device having an improved quality indicator. The storage medium may for example be a hard disk or an optical disk such as a CD or DVD. The reading device may further comprise means for controlling the reader in response to the quality indicator.

According to a third aspect of the invention, there is provided a method of generating a quality indicator for a decoded signal, the method comprises the steps of: determining a plurality of path metric differences, each path metric difference being a difference between at least two path metrics entering a state of a trellis based decoder; generating a measured distribution by ordering the plurality of path metric differences; determining parameters of an analysis distribution by fitting the analysis distribution to the measured distribution in a predetermined range of path metric differences; determining a quality indicator for the decoded signal in response to the analysis distribution; and wherein the analysis distribution is the sum of a first and second distribution in the predetermined range.

These and other aspects, features and advantages of the invention will be apparent from and elucidated with reference to the embodiment(s) described hereinafter.

### BRIEF DESCRIPTION OF THE DRAWINGS

An embodiment of the invention will be described, by way of example only, with reference to the drawings, in which

FIG. 1 illustrates a data reading device in accordance with an embodiment of the invention;

FIG. 2 illustrates an example of a measured path metric difference distribution for a 33 GB optical system having a run length constraint of one.

FIG. 3 illustrates an example of a measured path metric difference distribution and a fitted Gaussian distribution for a 33 GB optical system

FIG. 4 illustrates an example of a measured path metric difference distribution and a fitted Gaussian distribution for a 33 GB optical system;

FIG. 5 illustrates an example of an analysis path metric difference distribution comprising a first distribution and a second distribution;

FIG. 6 illustrates an example of a measured path metric difference distribution and a fitted Gaussian distribution for a 33 GB optical system without asymmetry;

FIG. 7 illustrates the difference between the measured path metric difference distribution and the fitted Gaussian distribution of FIG. 6;

FIG. 8 illustrates an example of measured path metric difference distribution and a fitted Gaussian distribution for a 33 GB optical system with asymmetry; and

FIG. 9 illustrates the difference between the measured path metric difference distribution and the fitted Gaussian distribution of FIG. 8.

### DESCRIPTION OF PREFERRED EMBODIMENTS

The following description focuses on an embodiment of the invention applicable to a reading device for reading data from an optical disc medium such as a CD or DVD. However, it will be appreciated that the invention is not limited to this application but may be applied to many other applications and decoded signals.

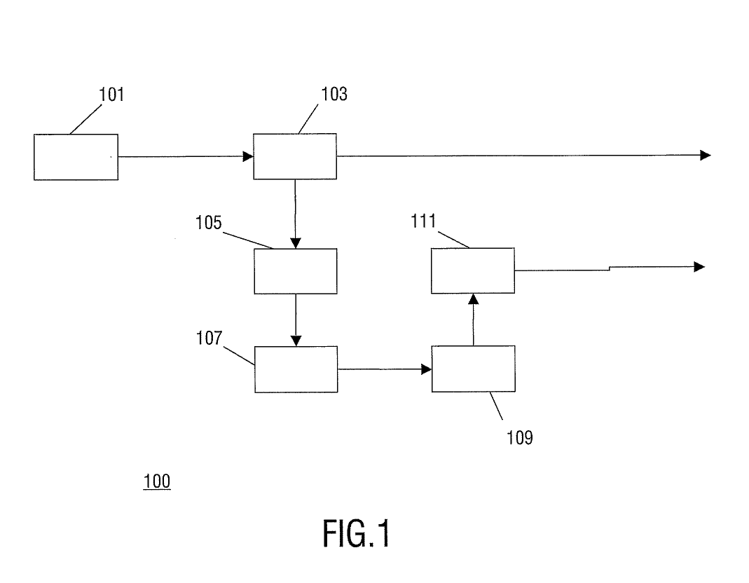

FIG. 1 illustrates a data reading device 100 in accordance with an embodiment of the invention.

The data reading device 100 comprises a data reader 101 which reads a data signal from an optical disk (not shown). The data signal is fed to a trellis based decoder 103 which performs a Partial Response Maximum Likelihood (PRML) decoding of the data signal as is well known to the person skilled in the art. In particular, the trellis based decoder 103 is a Viterbi decoder comprising a plurality of states for each bit. As is well known to the person skilled in the art, the Viterbi decoder calculates path metrics for each possible state transition for a new bit.

In the following description, it will be assumed that the calculated path metric for a state transition is a distance measure indicating the difference between the actual value of the data signal and an ideal value for that state transition. Hence, in this example, a lower value of the path metric corresponds to a higher probability of the corresponding state transition being the correct state transition. However, it will be appreciated that any suitable path metric measure may be used and in particular that the path metric may have increasing values for increasing probability of the state transition being a correct state transition.

In the embodiment, the Viterbi decoder determines the decoded bit sequence during a search back process by selecting a path that has the lowest combined path metric. Hence, for a given state, the state transition entering the state with the lowest path metric is selected.

The decoded signal is output from the data reader to an internal or external source (not shown). In addition, the data reading device 100 comprises functionality for determining a quality indicator which reflects an estimated quality of the decoded signal. In the specific embodiment a quality indicator in the form of an estimated bit error rate is calculated.

The Viterbi decoder 103 is coupled to a path metric processor 105. The path metric processor 105 receives path metric values from the Viterbi decoder 103 and generates a plurality of path metric differences. In particular, the path metric processor 105 generates a path metric difference for two state transitions leading to a state of the trellis which corresponds to the decoded sequence (or to a correct data sequence of the data is known). The path metric processor 105 generates a path metric difference for a large number of states corresponding to a large number of bits.

In the described embodiment, the path metric difference is simply calculated by subtracting the minimum path metric of a state from the second smallest path metric of that state. Hence, the path metric difference indicates the relative probability of the selected transition being the correct one. For example, a large path metric difference indicates that the distance and thus the path metric of the selected state transition is much smaller than for the closest state transition, and therefore that the first state transition can be selected with high certainty. A small value of the path metric difference indicates that there is little to choose between the two candidate state transitions.

Since the Viterbi decoder selects the state transition into a state that has the lowest path metric, a decoding bit error corresponds to a situation wherein an incorrect state transition into a state has a lower path metric than the correct state transition. Accordingly, the path metric difference between the correct state transition and the incorrect state transition should be a negative value. However, as the path metric processor 105 in the described example does not have any knowledge of the correct data but only of the decoded data (in other words a non data aided decoder is implemented), it simply determines a path metric difference by subtracting the second lowest path metric difference from the lowest path metric difference. Accordingly, the path metric processor 105 generates the absolute value of the path metric difference between the correct state transition and the closest incorrect state transition.

The path metric processor 105 is coupled to a measured distribution processor 107. The measured distribution processor 107 receives a large number of path metric differences from the path metric processor 105 and in response determines a measured distribution. In particular, the measured distribution processor 107 generates a probability density function by ordering the path metric difference samples from the path metric processor 105. Specifically, the measured distribution processor 107 may generate a histogram by ordering the path metric difference samples into intervals and determining the number of path metric difference samples in each interval. The histogram may be normalized by dividing the values of each interval by the total number of path metric difference samples.

The characteristics of the measured distribution will typically depend on the characteristics of the data signal input to the decoder. Preferably, many path metric difference samples are used and the central limit theorem may indicate that a Normal or Gaussian distribution may possibly be a reasonable assumption. Experiments and simulations have shown that in many cases, the measured distribution closely approaches a Gaussian distribution. For example, for an unconstrained hard disk or optical disk, the measured distribution tends to be essentially Gaussian.

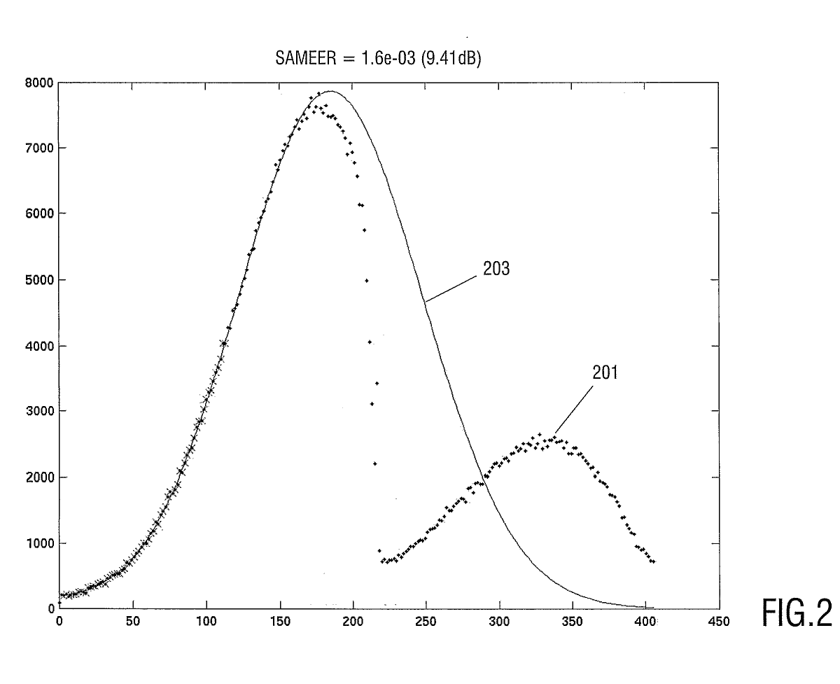

However, for constrained PRML optical disk reading systems, the measured distribution deviates from the Gaussian distribution. FIG. 2 illustrates an example of a measured distribution for a 33 GB optical system having a run length constraint d=1. In particular, FIG. 2 illustrates the histogram values of the measured distribution 201 as well as an overlaid Gaussian distribution 203. FIG. 2 illustrates the path metric difference along the X-axis and the number of samples for each path metric difference interval on the y-axis.

As can be seen, the measured distribution aligns with the Gaussian distribution for path metric difference values below the average path metric difference. However, for higher values of the path metric difference, the measured distribution deviates significantly from the Gaussian distribution as the run length constraint results in a shifting of the path metric differences to higher values. Thus, in the example of high density PRML optical systems with non-zero constraints, the measured distribution still approaches a Gaussian distribution for lower path metric differences.

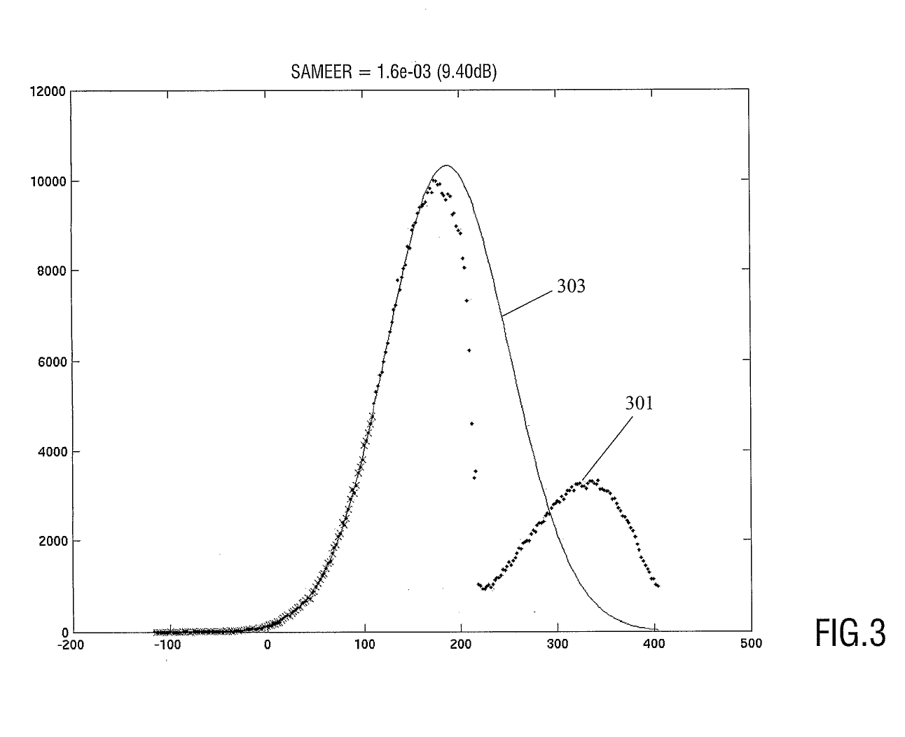

As mentioned previously, negative path metric differences between a known correct state transition and the closest state transition are indicative of a decoding bit error. FIG. 3 illustrates the histogram values of path metric differences calculated using knowledge of the correct decisions 301 as well as an overlaid Gaussian distribution 303. Thus, the measured distribution 201 of FIG. 2 corresponds to the histogram values of FIG. 3 except for the sign of the path metric differences corresponding to decoding errors.

The bit error rate of the system may be calculated by normalizing the distribution of FIG. 3 and integrating from −∞ to zero. Similarly, the bit error rate may be estimated by fitting a Gaussian probability density distribution to the measured distribution of FIG. 2 in order to extrapolate the measured distribution over the negative values and accordingly integrating this distribution from −∞ to zero.

However, such an approach is based on the assumption that a Gaussian distribution fitted to the measured distribution of FIG. 2 will result in a probability density function that will be representative on the negative axis (i.e. for a path metric difference from −∞ to zero). In other words, it is assumed that fitting a Gaussian distribution to the measured distribution of FIG. 2 will result in a probability density distribution closely resembling that of FIG. 3.

However, as the path metric differences generated by the path metric processor 105 are determined on detected data rather than on known data they are always non-negative. Thus, the measured distribution of FIG. 2 can only include positive values and represents a histogram of the absolute value of the path metric differences of FIG. 3. Thus, the path metric differences of the negative axis of the distribution of FIG. 3 is folded back to the positive axis in FIG. 2 resulting in increased values for especially low path metric difference values. It is clear that this results in a distortion to the assumed Gaussian distribution. Furthermore, the distortion increases in particular for higher data rates where more noise is present.

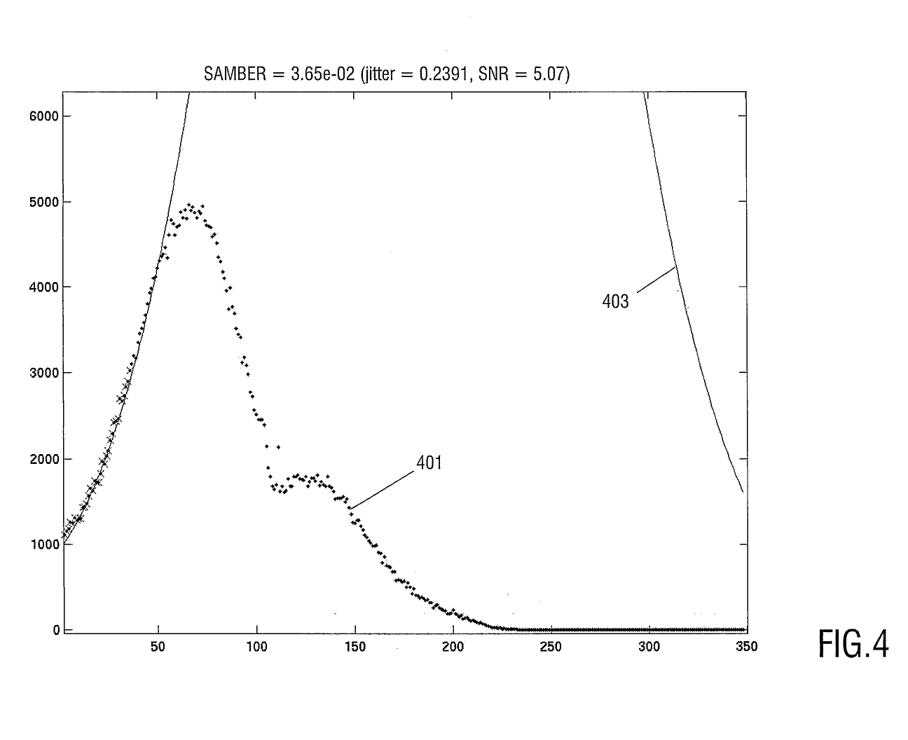

Accordingly, fitting a Gaussian distribution to the measured distribution and using this for determining a quality indicator results in an inaccurate measure. In particular, the distortion results in the estimated mean and standard variation of the Gaussian distribution not accurately reflecting the desired distribution. This is illustrated in FIG. 4 which illustrates a measured distribution 401 and a fitted Gaussian distribution 403. It is evident that the fitted distribution deviates substantially from the measured distribution and that accordingly an inaccurate bit error rate estimate will be calculated by integrating this distribution over the negative x-axis.

In the described embodiment, the measured distribution processor 107 is coupled to an analysis distribution processor 109. The analysis distribution processor 109 is operable to determine parameters of an analysis distribution by fitting the analysis distribution to the measured distribution. The analysis distribution comprises two distributions which are added together at least in a given range used for fitting.

The analysis distribution thus comprises a first and a second distribution. The analysis distribution processor 109 is operable to fit the analysis distribution such that the first distribution corresponds to the distribution of path metric difference that can be determined from known data (i.e. including negative values) whereas the second distribution corresponds to the path metric differences of the measured distribution which are folded onto the positive axis.

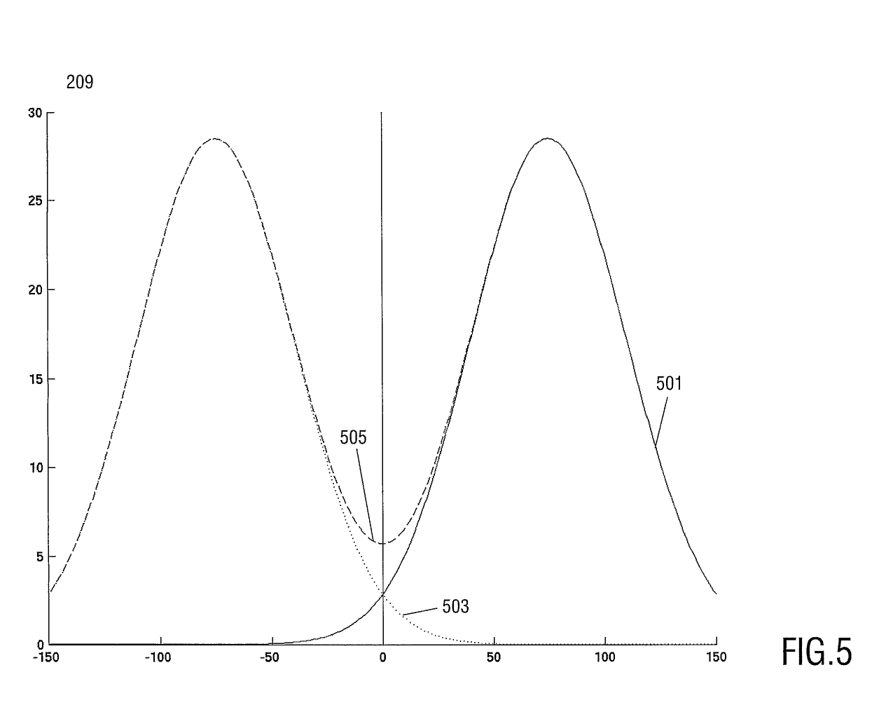

Specifically, the analysis distribution is comprised of two Gaussian distributions being added together. In the embodiment, the two distributions are mirror images of each other around a path metric difference of zero. Thus, the first distribution is a Gaussian distribution having a mean μ and standard deviation σ whereas the second distribution is a Gaussian distribution having a mean −μ and the same standard deviation σ. FIG. 5 illustrates the first distribution 501, the second distribution 503 and the analysis distribution 505 in accordance with the example.

As can be seen, for small path metric difference values the analysis distribution consists in two components wherein one reflects the desired Gaussian distribution whereas the other reflects distortion caused by the overlap into the positive path metric differences.

In the embodiment, the analysis distribution processor 109 fits the analysis distribution:

$$f ( x , μ , σ ) = \frac{A}{\sqrt{2 π} σ} [ exp ( \frac{- {( x - μ )}^{2}}{2 {σ}^{2}} ) + exp ( \frac{- {( x + μ )}^{2}}{2 {σ}^{2}} ) ]$$

to the measured distribution. Hence, the folding of the negative path metric differences into positive path metric differences is automatically taken into account during the fit procedure. No additional parameters need to be estimated and thus no complexity is added to the fit algorithm.

Accordingly, more accurate values of the parameters of a Gaussian distribution corresponding to that of FIG. 3 can be determined.

The analysis distribution processor 109 is coupled to a quality indicator processor 111 which determines the quality indicator in response to only the first distribution. Particularly, the first distribution corresponds to the distribution of the probability density function of path metric differences determined as the difference between the correct state transition and the incorrect state transition having the lowest value. If this path metric difference is negative, the decoder 103 has selected the wrong state transition and an error has occurred. Thus, the bit error rate may be calculated by integrating the first distribution from −∞ to zero.

Thus, the quality indicator processor 111 determines a bit error rate quality indicator from the formula:

$$erf ( x ) = {\int }_{- ∞}^{x} \frac{exp [ - {( x - μ )}^{2} / 2 {σ}^{2} ]}{\sqrt{2 π} σ}$$

where the mean μ and standard variation σ have been determined by fitting the analysis distribution. The function is also known as the error function.

Accordingly, an accurate bit error rate indicator may be generated.

Preferably, the fit of the analysis distribution to the measured distribution is limited to a suitable predetermined range. As previously mentioned and as illustrated in FIG. 2, the run length constraint of the described embodiment results in a non Gaussian distribution for path metric differences higher than the average path metric difference. Accordingly, the fitting of the analysis distribution is limited to evaluating a range of path metric differences from zero to an average path metric difference of the measured distribution. This ensures an accurate fit and that the deviance at higher path metric differences does not affect the calculated quality indicator.

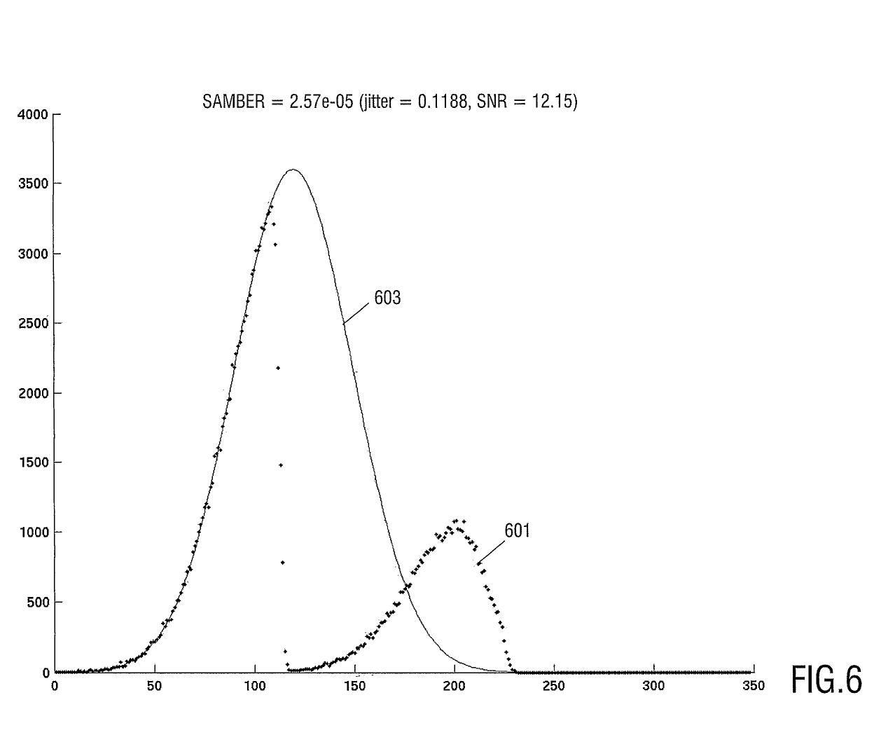

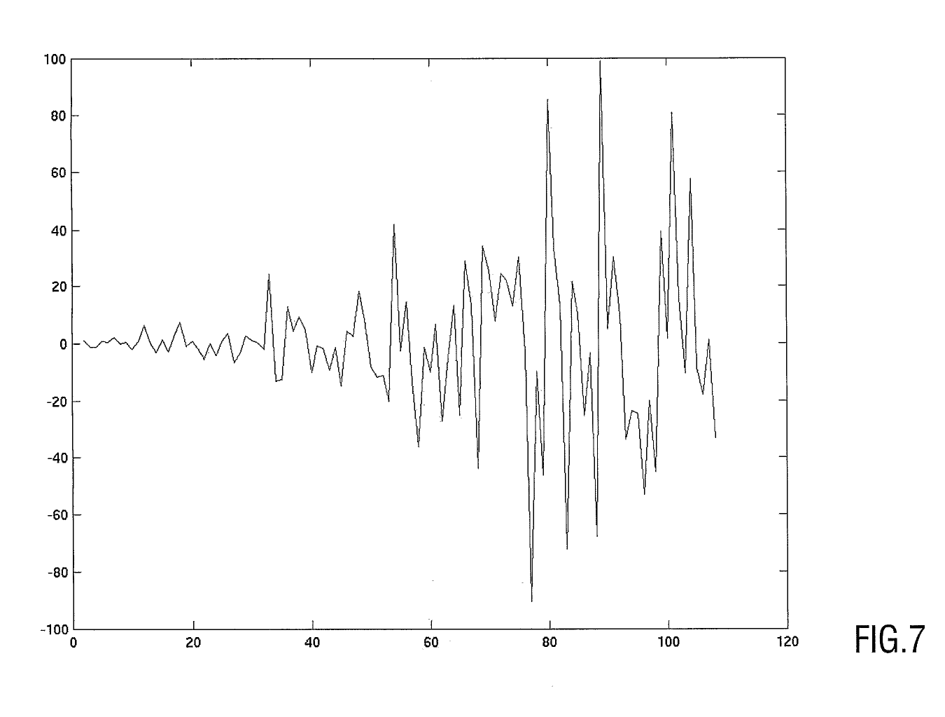

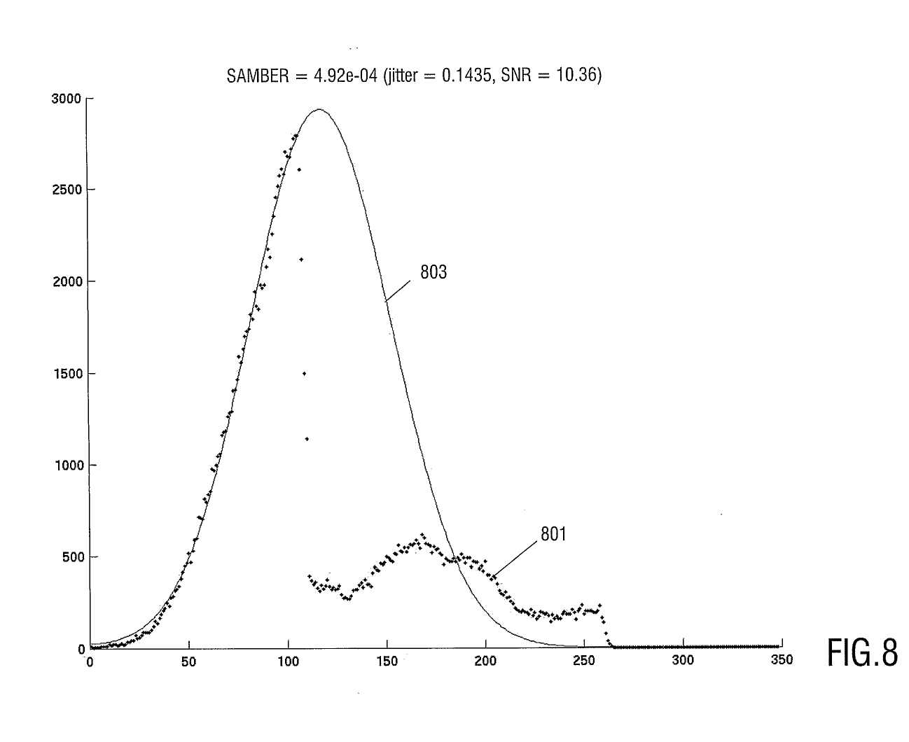

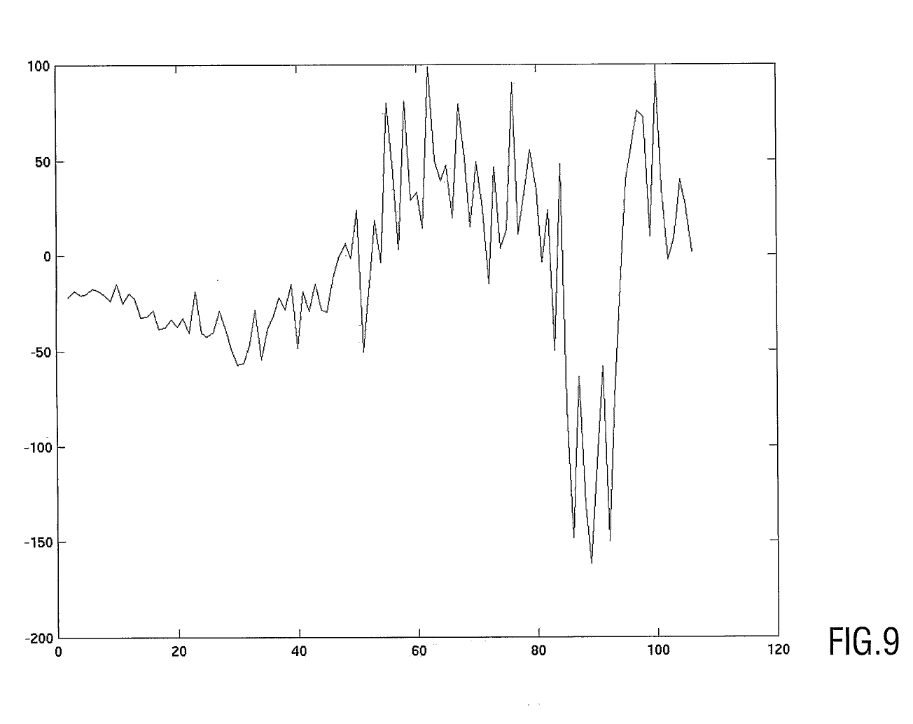

However, in many applications and in particular for optical disk systems significantly better results can be obtained when the fit range is limited to a smaller interval of the path metric differences. In particular, data points around the maximum of the histogram are preferably ignored when fitting the analysis function. For example, asymmetry in the signal from an optical disk gives rise to an additional peak to the left of the main peak, i.e. the shape of the measured distribution starts to deviate from the desired Gaussian shape. This is illustrated by the following example. FIG. 6 illustrates a measured distribution 601 and fitted Gaussian distribution 603 for a 33 GB optical system without asymmetry and FIG. 7 illustrates the difference between the measured distribution 601 and fitted Gaussian distribution 603 of FIG. 6. FIG. 8 illustrates a measured distribution 801 and fitted Gaussian distribution 803 for a 33 GB optical system with asymmetry and FIG. 9 illustrates the difference between the measured distribution 801 and fitted Gaussian distribution 803 of FIG. 8.

Using a range from zero to the mean path metric differences results in a fairly good fit for the situation without asymmetry (FIG. 6) but not for the situation with asymmetry (FIG. 8).

For a good estimate of the bit error rate, the low path metric difference values are the most important, because here the contributions from all peaks (i.e. also higher order, but possibly wide distributions) are taken into account. However, making the range too narrow will result in too few sample values and will result in a fit with insufficient reliability.

Testing of a fit procedure on a wide range of simulated as well as experimental data shows that a path metric difference range for fitting from zero up to a fraction of between 0.2 and 0.60 and preferably around 0.40 of the maximum histogram value provides particularly advantageous results.

A further improvement is to add the first histogram value to this range. This ensures that sufficient points are selected in case of a high date density, significant noise and/or asymmetry.

The invention can be implemented in any suitable form including hardware, software, firmware or any combination of these. However, preferably, the invention is implemented as computer software running on one or more data processors and/or digital signal processors. The elements and components of an embodiment of the invention may be physically, functionally and logically implemented in any suitable way. Indeed the functionality may be implemented in a single unit, in a plurality of units or as part of other functional units. As such, the invention may be implemented in a single unit or may be physically and functionally distributed between different units and processors.

Although the present invention has been described in connection with the preferred embodiment, it is not intended to be limited to the specific form set forth herein. Rather, the scope of the present invention is limited only by the accompanying claims. In the claims, the term comprising does not exclude the presence of other elements or steps. Furthermore, although individually listed, a plurality of means, elements or method steps may be implemented by e.g. a single unit or processor. Additionally, although individual features may be included in different claims, these may possibly be advantageously combined, and the inclusion in different claims does not imply that a combination of features is no feasible and/or advantageous. In addition, singular references do not exclude a plurality. Thus references to “a”, “an”, “first”,“second” etc do not preclude a plurality. Reference signs in the claims are provided merely as a clarifying example shall not be construed as limiting the scope of the claims in any way.

1. An apparatus for generating a quality indicator for a decoded signal, the apparatus comprising:
means for determining a plurality of path metric differences (105), each path metric difference being a difference between at least two path metrics entering a state of a trellis based decoder (103);
means for generating a measured distribution (107) by ordering the plurality of path metric differences;
means for determining parameters of an analysis distribution (109) by fitting the analysis distribution to the measured distribution in a predetermined range of path metric differences;
means for determining a quality indicator (111) for the decoded signal in response to the analysis distribution; and
wherein the analysis distribution is the sum of a first and second distribution in the predetermined range.

2. An apparatus as claimed in claim 1 wherein the means of determining the quality indicator (111) is operable to determine the quality indicator in response to only the first distribution.

3. An apparatus as claimed in claim 2 wherein the means of determining a quality indicator (111) is operable to determine the quality indicator in response to the first distribution in a range of path difference metrics below zero.

4. An apparatus as claimed in claim 1 wherein the means for determining the plurality of path metric differences (105) is operable to determine a path metric difference for a state of the trellis based decoder (103) as the absolute path metric difference between the best metric path and the second best metric path leading to the state, the state being designated a correct state by the trellis based decoder (103).

5. An apparatus as claimed in claim 1 wherein the predetermined range corresponds to path metric differences from zero to an average path metric difference of the measured distribution.

6. An apparatus as claimed in claim 1 wherein the predetermined range corresponds to path metric differences from zero to an upper path metric difference corresponding to a value of the measured distribution of a fraction of between 0.2 and 0.6 of the maximum value of the measured distribution.

7. An apparatus as claimed in claim 1 wherein the predetermined range corresponds to path metric differences from zero to an upper path metric difference corresponding to a value of the measured distribution of a fraction of around 0.4 of the maximum value of the measured distribution.

8. An apparatus as claimed in claim 1 wherein the second distribution is substantially equal to the first distribution mirrored around a path metric difference of substantially zero.

9. An apparatus as claimed in claim 1 wherein the first and second distributions are Gaussian distributions.

10. An apparatus as claimed in claim 1 wherein the quality indicator is a bit error rate.

11. A reading device (100) for reading from a storage medium; the reading device (100) comprising:
a data reader (101) for reading an encoded data signal from the storage medium;
a trellis based decoder (103) for generating a decoded data signal from the encoded data signal; and
an apparatus for generating a quality indicator for the decoded data signal in accordance with claim 1.

12. A method of generating a quality indicator for a decoded signal, the method comprises the steps of:
determining a plurality of path metric differences, each path metric difference being a difference between at least two path metrics entering a state of a trellis based decoder (103);
generating a measured distribution by ordering the plurality of path metric differences;
determining parameters of an analysis distribution by fitting the analysis distribution to the measured distribution in a predetermined range of path metric differences;
determining a quality indicator for the decoded signal in response to the analysis distribution;
wherein the analysis distribution is the sum of a first and second distribution in the predetermined range.

13. A computer program enabling the carrying out of a method according to claim 12.

14. A record carrier comprising a computer program as claimed in claim 13.
